(19) United States
(12) Patent Application Publication
(10) Pub. No.: US 2015/0087099 A1
(43) Pub. Date: Mar. 26, 2015

(54) METHOD FOR MANUFACTURING LIGHT EMITTING DIODE

(71) Applicant: ADVANCED OPTOELECTRONIC TECHNOLOGY, INC., Hsinchu Hsien (TW)

(72) Inventors: Shun-Kuei YANG, Hukou (TW); Tzu-Chien HUNG, Hukou (TW)

(21) Appl. No.: 14/482,566

(22) Filed: Sep. 10, 2014

(30) Foreign Application Priority Data
Sep. 25, 2013 (CN) 2013104401923

(51) Int. Cl. H01L 33/00; H01L 33/32; H01L 33/06

(52) U.S. Cl. CPC H01L 33/0075; H01L 33/0025; H01L 33/06; H01L 33/32
USPC 438/47

(57) ABSTRACT

A method for manufacturing a light emitting diode includes following steps: providing a substrate; forming a buffer layer on the substrate; forming a transitional layer on the buffer layer, the buffer layer being made of InGaN; forming an epitaxial layer on the transitional layer; activating the transitional layer by a way of radiating the transitional layer using laser; and when radiated with a laser, the transitional layer separates from the epitaxial layer.

### CROSS-REFERENCE TO RELATED APPLICATIONS

This application claims priority to Chinese Patent Application No. 201310440192.3 filed on Sep. 25, 2013 in the State Intellectual Property Office Of The P. R. C, the contents of which are incorporated by reference herein.

### FIELD

The disclosure relates to a method for manufacturing an LED (light emitting diode).

### BACKGROUND

A typical method for manufacturing light emitting diodes (LEDs) includes removing a substrate and a buffer layer formed on the substrate from an epitaxial layer, and it is almost always performed by etching.

### BRIEF DESCRIPTION OF THE DRAWINGS

Implementations of the present technology will now be described, by way of example only, with reference to the attached figures.

FIG. 1 is a cross-sectional view showing an LED in accordance with an exemplary embodiment of the present disclosure.

FIG. 2 is a cross-sectional view showing removing a substrate, a buffer layer and a transitional layer from the LED of FIG. 1.

### DETAILED DESCRIPTION OF EMBODIMENTS

It will be appreciated that for simplicity and clarity of illustration, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure. The description is not to be considered as limiting the scope of the embodiments described herein.

Several definitions that apply throughout this disclosure will now be presented. The term “comprising” means “including, but not necessarily limited to”; it specifically indicates open-ended inclusion or membership in a so-described combination, group, series and the like. The term “coupled” is defined as connected, whether directly or indirectly through intervening components, and is not necessarily limited to physical connections. The connection can be such that the objects are permanently connected or releasably connected. The term “electronically coupled” can include any coupling that is via a wired or wireless connection. The electronic coupling can be through one or more components or it can include a direct connection between the described components.

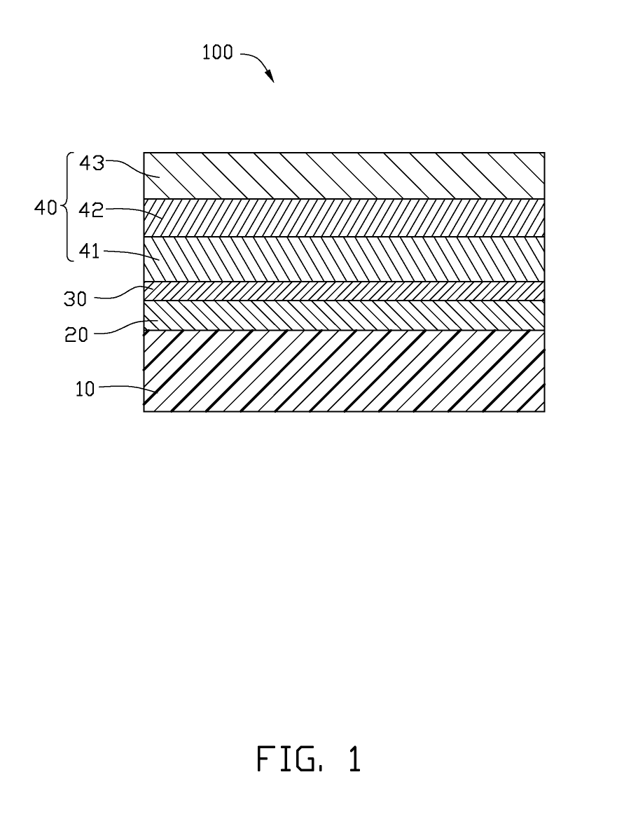

Referring to FIG. 1, providing a substrate 10. In at least one embodiment, the substrate 10 is made of sapphire.

Forming a buffer layer 20 on the substrate 10. The buffer layer 20 is formed by a way of Metal-Organic Chemical Vapor Deposition (MOCVD), Molecular Beam Epitaxy (MBE), or Hydride Vapor Phase Epitaxy (HVPE). In at least one embodiment, the buffer layer 20 is an un-doped GaN layer.

Forming a transitional layer 30 on the buffer layer 20. The transitional layer 30 is formed by a way of Metal-Organic Chemical Vapor Deposition (MOCVD), Molecular Beam Epitaxy (MBE), or Hydride Vapor Phase Epitaxy (HVPE). In at least one embodiment, the transitional layer 30 is an InGaN film, and a thickness of the transitional layer 30 varies from 100 A to 200 A.

Forming an epitaxial layer 40 on the transitional layer 30. The transitional layer 30 is formed by a way of Metal-Organic Chemical Vapor Deposition (MOCVD), Molecular Beam Epitaxy (MBE), or Hydride Vapor Phase Epitaxy (HVPE). The epitaxial layer 40 includes a first semiconductor layer 41, an active layer 42 and a second semiconductor layer 43. The first semiconductor layer 41 is formed on the transitional layer 30, the active layer 42 is formed on the first semiconductor 41 and the second semiconductor layer 43 is formed on the active layer 42. In at least one embodiment, the first semiconductor 41 is an N-type GaN layer, the active layer 42 is a multi-quantum well GaN layer, and the second semiconductor 43 is a P-type GaN layer.

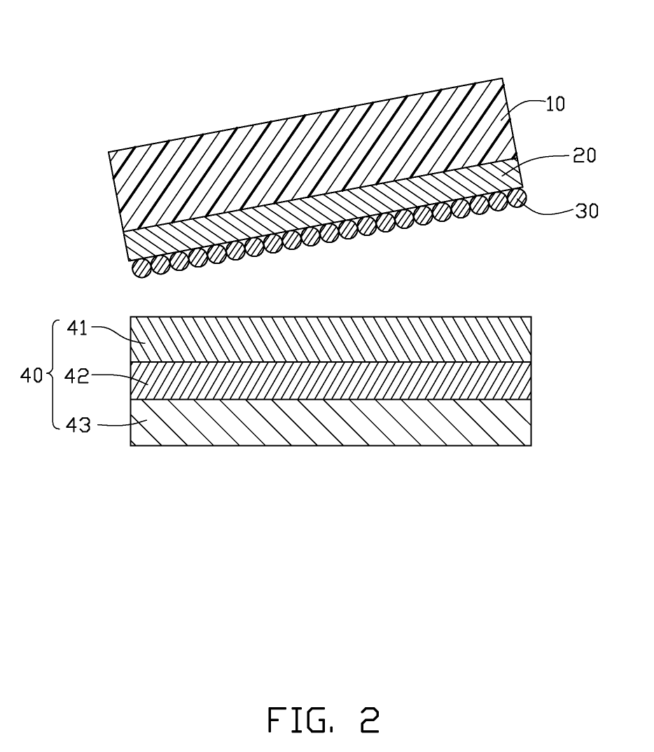

Referring to FIG. 2, activating the transitional layer 30 by a way of radiating the transitional layer 30 using a laser. In at least one embodiment, the transitional layer 30 is subjected to temperatures of 1000-1400° C., and is radiated by laser with wavelengths from 420 nm to 520 nm. And because the wavelength of the laser is larger than 420 nm, the transitional layer 30 can be activated by the laser without affecting the buffer layer 20. And meanwhile, the transitional layer 30 made of InGaN is heated to contract to represent ball-shaped configurations, which makes the transitional layer 30 separate from the epitaxial layer 40 to obtain an individual LED without the substrate 10, the buffer layer 20 and the transitional layer 30.

According to the above description of the embodiment of the disclosure, by a way of forming the InGaN transitional layer 30 between the buffer layer 20 and the epitaxial layer 40, and radiating the InGaN transitional layer 30 using layer with wavelengths from 420 nm to 520 nm in temperatures 1000-1400° C., the transitional layer 30 is contracted to separate from the epitaxial layer 40.

It is to be further understood that even though numerous characteristics and advantages have been set forth in the foregoing description of embodiments, together with details of the structures and functions of the embodiments, the disclosure is illustrative only; and that changes may be made in detail, including in matters of shape, size, and arrangement of parts within the principles of the disclosure to the full extent indicated by the broad general meaning of the terms in which the appended claims are expressed.

The embodiments shown and described above are only examples. Many details are often found in the art such as the other features of a method for manufacturing an LED. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A method of manufacturing a light emitting diode comprising:
providing a substrate;
forming a buffer layer on the substrate;
forming a transitional layer on the buffer layer;
forming an epitaxial layer on the transitional layer; and
radiating the transitional layer with a laser;
wherein, when radiated with a laser, the transitional layer separates from the epitaxial layer.

2. The method of claim 1, wherein the wavelength of the laser is larger than 420 nm.

3. The method of claim 1, wherein the wavelength of the laser is 420 nm-520 nm.

4. The method of claim 1, wherein the transitional layer is activated in temperatures of 1000-1400° C.

5. The method of claim 1, wherein the buffer layer is an un-doped GaN layer.

6. The method of claim 1, wherein the buffer layer, the transitional layer and the epitaxial layer are formed by a way of Metal-Organic Chemical Vapor Deposition, Molecular Beam Epitaxy, or Hydride Vapor Phase Epitaxy.

7. The method of claim 1, wherein the substrate is made of sapphire.

8. The method of claim 1, wherein the epitaxial layer comprises a first semiconductor, an active layer formed on the first semiconductor, and an second semiconductor formed on the active layer.

9. The method of claim 1, wherein a thickness of the transitional layer varies from 100 A to 200 A.

10. The method of claim 1, wherein the transitional layer is radiated by laser to contract to ball-shaped configurations to separate from the epitaxial layer.

11. The method of claim 1, wherein the transitional layer is made of InGaN.

12. A method for manufacturing a light emitting diode comprising:
providing a substrate;
forming a buffer layer on the substrate;
forming a transitional layer on the buffer layer, the buffer layer being made of InGaN;
forming an epitaxial layer on the transitional layer;
activating the transitional layer by a way of radiating the transitional layer using laser to remove the substrate and the buffer layer from the epitaxial layer; and
wherein the wavelength of laser is 420 nm-520 nm, and the transitional layer is radiated by the laser in temperatures of 1000-1400° C.

13. The method of claim 12, wherein the transitional layer is radiated by the laser to represent ball-shaped configurations.
